(19) United States
(12) Patent Application Publication
(10) Pub. No.: US 2026/0269798 A1
(43) Pub. Date: Sep. 10, 2026

(54) CURRENT SHUNT MONITORING SYSTEM

(71) Applicants: Faraday Technology Corporation, Suzhou (CN); FARADAY TECHNOLOGY CORPORATION, Hsinchu City (TW)

(72) Inventors: Feng XU, Hsinchu City (TW); Meng ZHAO, Hsinchu City (TW); Chih-Yuan HUNG, Hsinchu City (TW)

(21) Appl. No.: 19/306,585

(22) Filed: Aug. 21, 2025

(30) Foreign Application Priority Data
Mar. 5, 2025 (CN) 202510258660.8

(51) Int. Cl. H03F 3/45; H03F 1/30; H03G 3/30

(52) U.S. Cl. CPC H03F 3/45968; H03F 1/30; H03F 3/45475; H03G 3/301; H03F 2200/261; H03F 2203/45048; H03F 2203/45616

(57) ABSTRACT

A current shunt monitoring system is provided. A standard calibration procedure is used to calibrate the error generated by each circuit in the current shunt monitoring system. The error at least includes the offset of the circuit and the CMRR change of the circuit. An advanced calibration procedure is further provided to eliminate the gain deviation and the offset deviation of the AFE circuit.

This application claims the benefit of People's Republic of China application serial No. 202510258660.8, filed Mar. 5, 2025, the subject matter of which is incorporated herein by reference.

### FIELD OF THE INVENTION

The present invention relates to a monitoring system, and more particularly to a current shunt monitoring system.

### BACKGROUND OF THE INVENTION

FIG. 1 schematically illustrates the architecture of a conventional current shunt monitor. As shown in FIG. 1, the current shunt monitor 100 includes an analog front end circuit (AFE circuit) 110 and an analog-to-digital circuit (ADC circuit) 120. Generally, the current shunt monitor 100 is designed inside an IC chip 180. The IC chip 180 is soldered on a circuit board 190. In addition, a resistor R is soldered on the circuit board 190. For example, the circuit board 190 is a printed circuit board (PCB).

As shown in FIG. 1, the two terminals of the resistor R on the circuit board 190 are respectively connected to two pins 101 and 102 of the IC chip 180. In addition, the two pins 101 and 102 of the IC chip 180 are also connected to the AFE circuit 110 in the current shunt monitor 100. Consequently, so that the AFE circuit 110 can detect the voltage drop across the two terminals of the resistor R.

Generally, for supporting a high current detection range and a high resolution, the resistor R soldered on the circuit board 190 usually has a tiny resistance value. As a consequence, the current I flowing through the resistor R results in a smaller voltage drop I×R. The voltage drop I×R is equal to an input voltage V_{IN}, and the input voltage V_{IN} is inputted into the current shunt monitor 100. For example, the resistance value of the resistor R is about 0.5Ω~2Ω, and the voltage drop I×R is approximately at mV level. Generally, since resistors R with very accurate resistance values can be purchased on the market and soldered on the circuit board 190, there is almost no error in the voltage drop I×R, and it is not necessary to calibrate the resistor R. Since the input signal received by the current shunt monitor 100 is at the mV level, the AFE circuit 110 needs to be designed with a high gain to amplify the input voltage V_{IN}. In this way, the ADC circuit 120 can generate a high-resolution digital value D_{ADC}.

Since the accuracy needs to be taken into account and the input voltage V_{IN} is at the mV level, the offset of the AFE circuit 110 needs to be maintained at the μV level. Furthermore, other factors need to be paid attention. For example, the AFE circuit 110 has a high common mode rejection ratio (CMRR), and the ADC circuit 120 has a low offset. These factors will increase the design difficulty of the current shunt monitor 100.

### SUMMARY OF THE INVENTION

An embodiment of the present invention provides a current shunt monitoring system. The current shunt monitoring system is connected to a resistor. A current flows through the resistor to generate a voltage drop. The current shunt monitoring system includes an analog front end circuit, an analog-to-digital circuit and a digital calibration circuit. A first input terminal of the analog front end circuit is connected to a first terminal of the resistor. A second input terminal of the analog front end circuit is connected to a second terminal of the resistor. An input terminal of the analog-to-digital circuit is connected to an output terminal of the analog front end circuit to receive an output voltage. The output voltage is converted by the analog front end circuit. An input terminal of the digital calibration circuit is connected to an output terminal of the analog-to-digital circuit. When a first calibration procedure is performed, the analog front end circuit receives an input voltage, the input voltage is zero, and the analog-to-digital circuit generates a first digital error value to the digital calibration circuit. After the first calibration procedure is completed, a normal operation procedure is performed, wherein during the normal operation procedure, the input voltage received by the analog front end circuit is equal to the voltage drop, and the analog-to-digital circuit generates a first digital operation value to the digital calibration circuit. During the normal operation procedure, the digital calibration circuit subtracts the first digital error value from the first digital operation value to obtain a summed value, multiplies the summed value by a correction ratio to obtain a calibrated output value, and outputs the calibrated output value.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) schematically illustrates the architecture of a conventional current shunt monitor;

FIG. 2 schematically illustrates the architecture of a current shunt monitoring system according to an embodiment of the present invention;

FIG. 3 is a schematic circuit diagram illustrating the detailed circuitry structure of a current shunt monitoring system according to a first embodiment of the present invention;

FIGS. 4A and 4B are schematic circuit diagrams illustrating a standard calibration procedure for the current shunt monitoring system in the first embodiment of the present invention;

FIG. 5 is a schematic circuit diagram illustrating the detailed circuitry structure of a current shunt monitoring system according to a second embodiment of the present invention;

FIGS. 6A, 6B, 6C and 6D are schematic circuit diagrams illustrating a first example of an advanced calibration procedure for the current shunt monitoring system in the second embodiment of the present invention; and

FIGS. 7A, 7B, 7C, 7D, 7E and 7F are schematic circuit diagrams illustrating a second example of an advanced calibration procedure for the current shunt monitoring system in the second embodiment of the present invention.

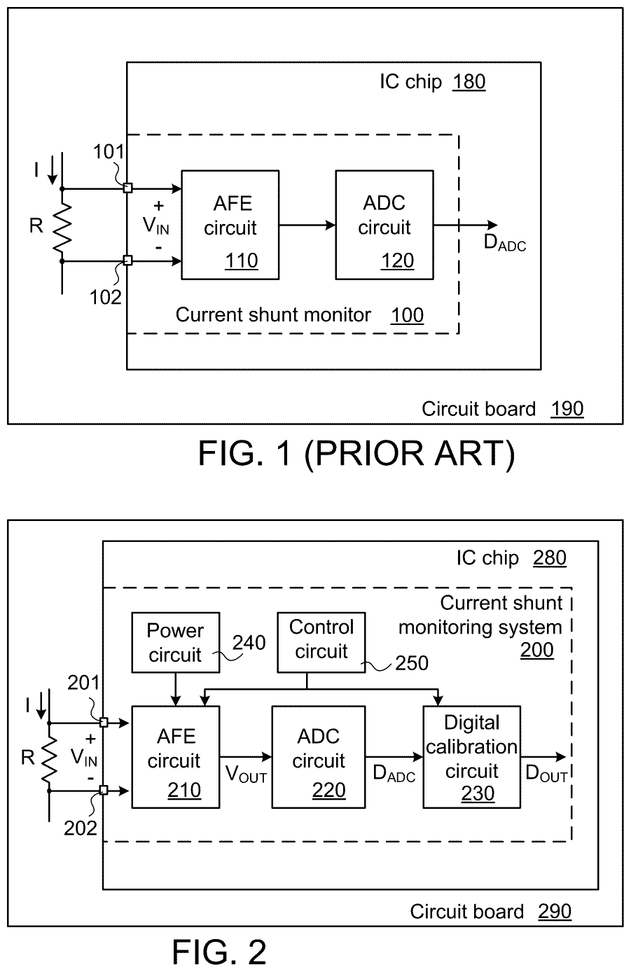

### DETAILED DESCRIPTION OF PREFERRED EMBODIMENTS

The present invention provides a current shunt monitoring system. A standard calibration procedure is used to calibrate the error generated by each circuit in the current shunt monitoring system. The error at least includes the offset of the circuit and the CMRR change of the circuit. The present invention further provides an advanced calibration procedure to eliminate the gain deviation and the offset deviation of the AFE circuit.

FIG. 2 schematically illustrates the architecture of a current shunt monitoring system according to an embodiment of the present invention. As shown in FIG. 2, the current shunt monitoring system 200 includes an analog front end circuit (AFE circuit) 210, an analog-to-digital circuit (ADC circuit) 220, a digital calibration circuit 230, a power circuit 240 and a control circuit 250. Similarly, the current shunt monitoring system 200 is designed in an IC chip 280, and the IC chip 280 is soldered on a circuit board 290. Furthermore, a resistor R is soldered on the circuit board 290. The resistance value of this resistor R is very accurate. Consequently, it is regarded that the voltage drop I×R is almost no error.

The power circuit 240 is connected to the AFE circuit 210. The control circuit 250 is connected to the AFE circuit 210 and the digital correction circuit 230. Through the power circuit 240, a bias point of the output voltage V_{OUT} of the AFE circuit 210 can be set. Consequently, there is enough headroom between the output voltage V_{OUT} of the AFE circuit 210 and the source voltage.

During the normal operation, the two input terminals of the AFE circuit 210 are respectively connected to the two terminals of the resistor R through the two pins 201 and 202 of the IC chip 280 to receive the input voltage V_{IN}. The input voltage V is the voltage drop I×R when the current I flows through the resistor R. The AFE circuit 210 can amplify the input voltage V_{IN} and generate an output voltage V_{OUT}.

The ADC circuit 220 receives the output voltage V_{OUT} and performs an analog-to-digital conversion. During the calibration process of the current shunt monitoring system 200, the ADC circuit 220 generates a digital error value according to the output voltage V_{OUT} and issues the digital error value to the digital calibration circuit 230. The digital error value is temporarily stored in the digital correction circuit 230. Thereafter, during the normal operation of the current shunt monitoring system 200, the ADC circuit 220 generates a digital operation value D_{ADC} according to the output voltage V_{OUT} and issues the digital operation value D_{ADC} to the digital correction circuit 230. Furthermore, according to the digital error value and the digital operation value D_{ADC}, the digital correction circuit 230 generates a calibrated output value D_{OUT}. This calibrated output value D_{OUT} can accurately reflect the voltage drop across the resistor R. Moreover, since the resistance value of the resistor R is known, the calibrated output value D_{OUT} can also accurately reflect the magnitude of the current I flowing through the resistor R.

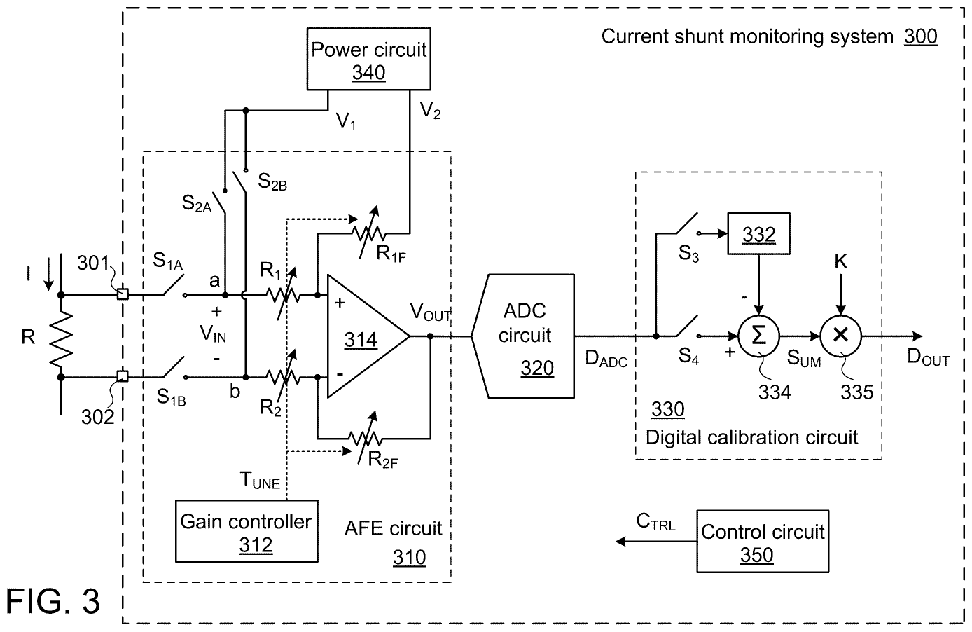

FIG. 3 is a schematic circuit diagram illustrating the detailed circuitry structure of a current shunt monitoring system according to a first embodiment of the present invention. The current shunt monitoring system 300 includes an analog front end circuit (AFE circuit) 310, an analog-to-digital circuit (ADC circuit) 320, a digital calibration circuit 330, a power circuit 340 and a control circuit 350. Similarly, the current shunt monitoring system 300 is designed in an IC chip, and the IC chip is soldered on a circuit board. For succinctness, the IC chip and the circuit board are not shown. In addition, the two terminals of the resistor R are connected to two pins 301 and 302, respectively.

The first power terminal of the power circuit 340 outputs a first voltage V₁, and the second power terminal of the power circuit 340 outputs a second voltage V₂. Generally, the first voltage V₁ is greater than the second voltage V₂.

The AFE circuit 310 includes a differential amplifier 314, a gain controller 312, four variable resistors R₁, R_{1F}, R₂, R_{2F}, and four switches S_{1A}, S_{1B}, S_{2A}, S_{2B}.

The first terminal of the switch S_{1A} is connected to the pin 301, and the second terminal of the switch S_{1A} is connected to the node a. The first terminal of the switch S_{1B} is connected to the pin 302, and the second terminal of the switch S_{1B} is connected to the node b. A terminal of the switch S_{2A} is connected to the first power terminal of the power circuit 340 to receive the first voltage V₁, and the other terminal of the switch S_{2A} is connected to the node a. A terminal of the switch S_{2B} is connected to the first power terminal of the power circuit 340 to receive the first voltage V₁, and the other terminal of the switch S_{2B} is connected to the node b.

The first terminal of the variable resistor R₁ is connected to the node a, and the second terminal of the variable resistor R₁ is connected to the positive input terminal of the differential amplifier 314. The first terminal of the variable resistor RIF is connected to the second power supply terminal of the power supply circuit 340 to receive the second voltage V₂, and the second terminal of the variable resistor RIF is connected to the positive input terminal of the differential amplifier 314. The first terminal of the variable resistor R₂ is connected to the node b, and the second terminal of the variable resistor R₂ is connected to the negative input terminal of the differential amplifier 314. The first terminal of the variable resistor R_{2F} is connected to the output terminal of the differential amplifier 314, and the second terminal of the variable resistor R_{2F} is connected to the negative input terminal of the differential amplifier 314.

Furthermore, the gain controller 312 can output an adjustment signal T_{UNE} to the control terminals of the variable resistors R₁, R_{1F}, R₂ and R_{2F} to adjust the resistance values of the variable resistors R₁, R_{1F}, R₂ and R_{2F}. When one of the resistance values of the variable resistors R₁, R_{1F}, R₂ and R_{2F} is subjected to a change, the gain of the differential amplifier 314 will be also subjected to a change. In other words, the gain controller 312 issues the adjustment signal T_{UNE} to adjust the gain of the differential amplifier 314. Generally, under control of the gain controller 312, the ratio of the resistance value of the resistor RIF to the resistance value of the resistor R₁ is equal to the ratio of the resistance value of the resistor R_{2F} to the resistance value of the resistor R₂. That is, (RIF/R₁) is equal to (R_{2F}/R₂). For example, the gain controller 312 controls the resistor RIF and the resistor R_{2F} to have the same resistance value, and the gain controller 312 controls the resistor R₁ and the resistor R₂ to have the same resistance value.

In this embodiment, the common voltage of the differential amplifier 314 is set according to the first voltage V₁, and the first voltage V₁ is used to achieve better calibration accuracy while compensating for the CMRR induced errors. The minimum value of the output voltage V_{OUT} of the differential amplifier 314 is set according to the second voltage V₂. Consequently, the differential amplifier 314 can easily support the input voltage V_{IN} as low as 0 (i.e., when the current I is 0) eliminate errors during calibration.

Furthermore, the input terminal of the ADC circuit 320 receives the output voltage V_{OUT} and performs the analog-to-digital conversion. For example, during the normal operation, the output terminal of the ADC circuit 320 generates the digital operation value D_{ADC}.

The input terminal of the digital calibration circuit 330 is connected to the output terminal of the ADC circuit 320. The digital calibration circuit 330 includes an adder 334, a multiplier 335, a storage device 332 and two switches S₃ and S₄. The first terminal of the switch S₃ is connected to the output terminal of the ADC circuit 320. The second terminal of the switch S₃ is connected to the input terminal of the storage device 332. The output terminal of the storage device 332 is connected to the first input terminal of the adder 334. The first terminal of the switch S₄ is connected to the output terminal of the ADC circuit 320. The second terminal of the switch S₄ is connected to the second input terminal of the adder 334. By the adder 334, the value received at the first input terminal is subtracted from the value received at the second input terminal. The result of the subtraction is the summed value SUM. The summed value SUM is outputted from the output terminal of the adder 334. The first input terminal of the multiplier 335 is connected to the output terminal of the adder 334 to receive the summed value SUM. The second input terminal of the multiplier 335 receives a correction ratio K. The result of multiplying the summed value SUM and the correction ratio K is the calibrated output value D_{OUT}. The calibrated output value D_{OUT} is outputted from the output terminal of the multiplier 335. The correction ratio K can be set to a constant. For example, K is equal to 1.

The control circuit 350 generates a control signal CTRL to control the on/off states of the switches S_{1A}, S_{1B}, S_{2A} and S_{2B} in the AFE circuit 310 and the switches S₃ and S₄ in the digital correction circuit 330. For example, the control signal CTRL contains six sub-control signals (not shown). These six sub-control signals are respectively transmitted to the control terminals of the corresponding switches S_{1A}, S_{1B}, S_{2A}, S_{2B}, S₃ and S₄ to control the on/off states of the switches S_{1A}, S_{1B}, S_{2A}, S_{2B}, S₃ and S₄.

A standard calibration procedure of the current shunt monitoring system in the first embodiment will be described as follows. The standard calibration procedure includes an initial calibration procedure and a normal operation procedure. The initial calibration procedure may be regarded as a first calibration procedure.

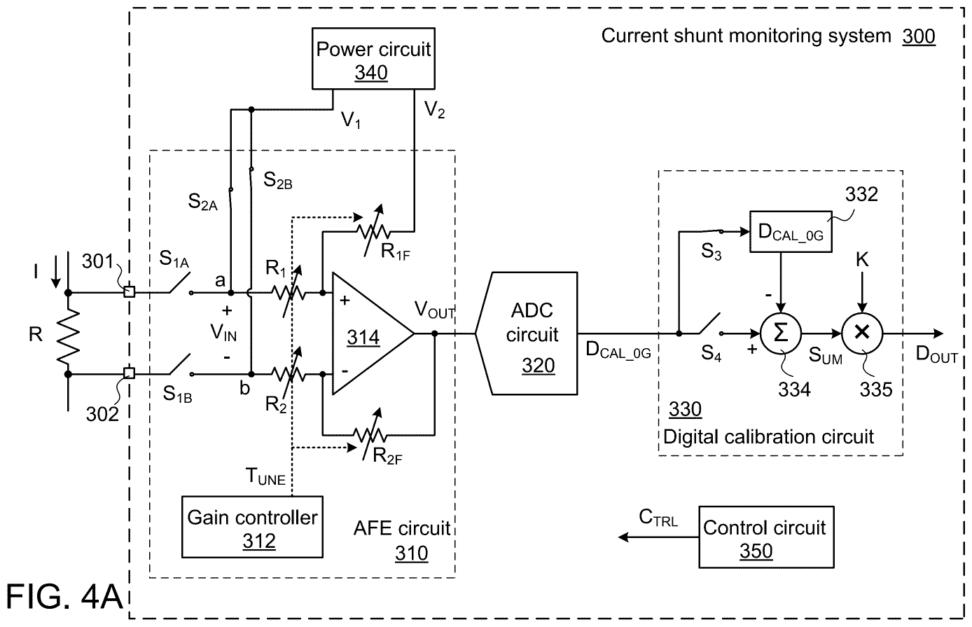

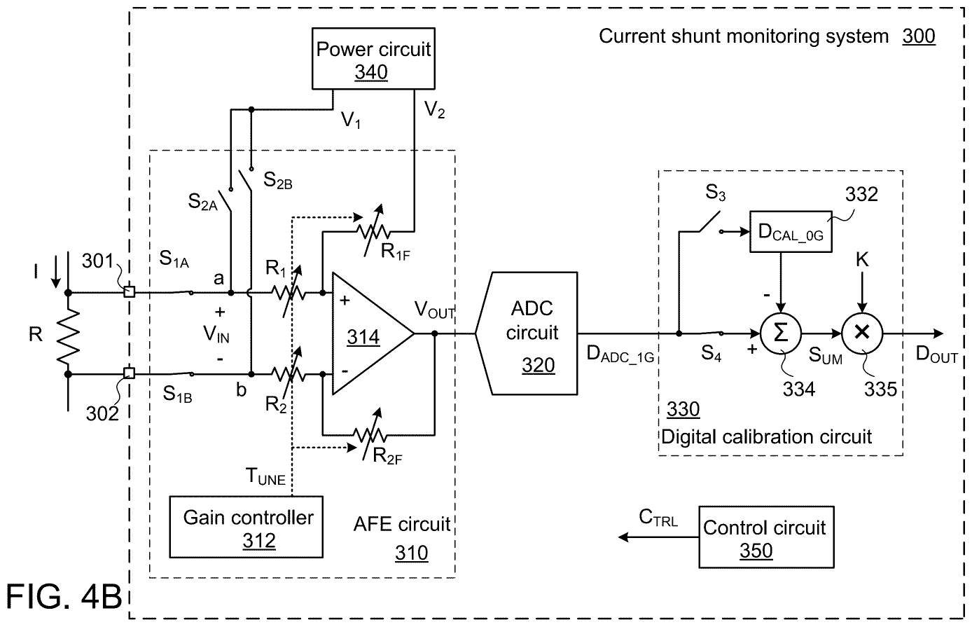

FIGS. 4A and 4B are schematic circuit diagrams illustrating a standard calibration procedure for the current shunt monitoring system in the first embodiment of the present invention. After the initial calibration procedure is performed, the normal operation procedure of the current shunt monitoring system 300 will be performed.

Please refer to FIG. 4A. During the initial calibration procedure, the switches S_{1A}, S_{1B} and S₄ are in the off state and the switches S_{2A}, S_{2B} and S₃ are in the on state under control of the control circuit 350. In this situation, the input terminals of the AFE circuit 310 are not connected to the external resistor R, and the input terminals of the AFE circuit 310 receive the same first voltage V₁. In other words, the input voltage V_{IN} is equal to zero. Consequently, the output voltage V_{OUT} is generated according to the error of the differential amplifier 314. The input offset in the error of the differential amplifier 314 will be amplified, and other errors of the differential amplifier 314 will not be amplified. In addition, the error of the ADC circuit 320 will not be amplified. In case that the gain of the differential amplifier 314 for performing the initial calibration procedure is G, the ADC circuit 320 generates a digital error value D_{CAL_0G}, and the digital error value D_{CAL_0G} is stored in the storage device 332 of the digital calibration circuit 330.

In other words, D_{CAL_0G}=V_{OS}×(G+1)+V_{AFE_ERR}+V_{ADC_ERR}+V₂. In this formula, V_{OS} is the input offset of the differential amplifier 314 during the initial calibration procedure, the input offset V_{OS} is amplified by (G+1) times, V_{AFE_ERR} indicates other errors of the differential amplifier 314, V_{ADC_ERR} is the error of the ADC circuit 320, and the minimum value of the output voltage V_{OUT} of the differential amplifier 314 is set according to the second voltage V₂. In addition, G is the gain of the differential amplifier 314, and G is controlled by the gain controller 312. For example, G=(R_{2F}/R₂)=(R_{1F}/R₁).

After the initial calibration procedure is completed, the normal operation procedure of the current shunt monitoring system 300 is performed, in which the gain of the differential amplifier 314 is G. Please refer to FIG. 4B. During the normal operation procedure, the switches S_{1A}, S_{1B} and S₄ are in the on state and the switches S_{2A}, S_{2B} and S₃ are in the off state under control of the control circuit 350. In this situation, the input terminals of the AFE circuit 310 are connected to the external resistor R, and the AFE circuit 310 starts to detect the voltage drop I×R across the resistor R. In other words, the input voltage V_{IN} is equal to the voltage drop I×R. Meanwhile, the output voltage V_{OUT} is generated according to the input voltage V_{IN} and the error, the output terminal of the ADC circuit 320 generates the digital operation value D_{ADC}. That is, in case that the gain of the differential amplifier 314 is G in the normal operation procedure, the ADC circuit 320 generates the digital operation value D_{ADC_1G}.

That is, D_{ADC_1G}=V_{IN}×G+V_{OS}×(G+1)+V_{AFE_ERR}+V_{ADC_ERR}+V₂. The input voltage V_{IN} is equal to the voltage drop I×R. In addition, D_{ADC_1G}=(I×R)×G+V_{CAL_0G}, wherein V_{CAL_0G} may be regarded as a non-ideal value.

Furthermore, the digital error value D_{CAL_0G} stored in storage device 332 of the digital calibration circuit 330 corresponding to the initial calibration procedure is outputted. Consequently, the digital calibration circuit 330 generates the calibrated output value D_{OUT}. The calibrated output value D_{OUT} may be expressed as: D_{OUT}=(D_{ADC_1G}−D_{CAL_0G})×K=(I×R)×G×K. That is, in case that the correction ratio K is set to 1 in the normal operation procedure of the current shunt monitoring system 300, the calibrated output value D_{OUT} from the digital calibration circuit 330 may be expressed as: D_{OUT}=(I×R)×G.

From the above descriptions, the non-ideal value in the calibrated output value D_{OUT} from the digital calibration circuit 330 is eliminated during the normal operation procedure. That is, only the ideal value is retained. Under this circumstance, the calibrated output value D_{OUT} can accurately reflect the voltage drop I×R across the resistor R. Furthermore, since the resistance value of the resistor R is known, the calibrated output value D_{OUT} can also accurately reflect the magnitude of the current I flowing through the resistor R.

In the standard calibration procedure of the current shunt monitoring system, the correction ratio K is set to 1. In practice, the correction ratio K can also be set to any other appropriate value according to the actual operation of the current shunt monitoring system 300. For example, it is assumed that the gain of the AFE circuit 310 is set to G. However, it is expected that the gain will be changed from G to 1.1G during the normal operation procedure. Under this circumstance, the correction ratio K can be set to (1/1.1), and the calibrated output value D_{OUT} can be adjusted to the ideal value.

In the above standard calibration procedure, the gain deviation and the offset deviation are very small and can be ignored. However, if the current shunt monitoring system 300 is operated in a bad environment, the gain deviation and the offset deviation are serious and cannot be ignored.

For example, during the initial calibration procedure, the ambient temperature of the current shunt monitoring system 300 is relatively low, and the gain deviation and the offset deviation are very small. However, during the normal operation procedure, the ambient temperature of the current shunt monitoring system 300 becomes higher and higher, and the gain deviation and the offset deviation of the AFE circuit 310 become more and more serious. For overcoming these drawbacks, the present invention further provides a current shunt monitoring system according to a second embodiment. In this embodiment, the current shunt monitoring system performs an advanced calibration process to dynamically adjust the correction ratio K to improve the calibrated output value D_{OUT}.

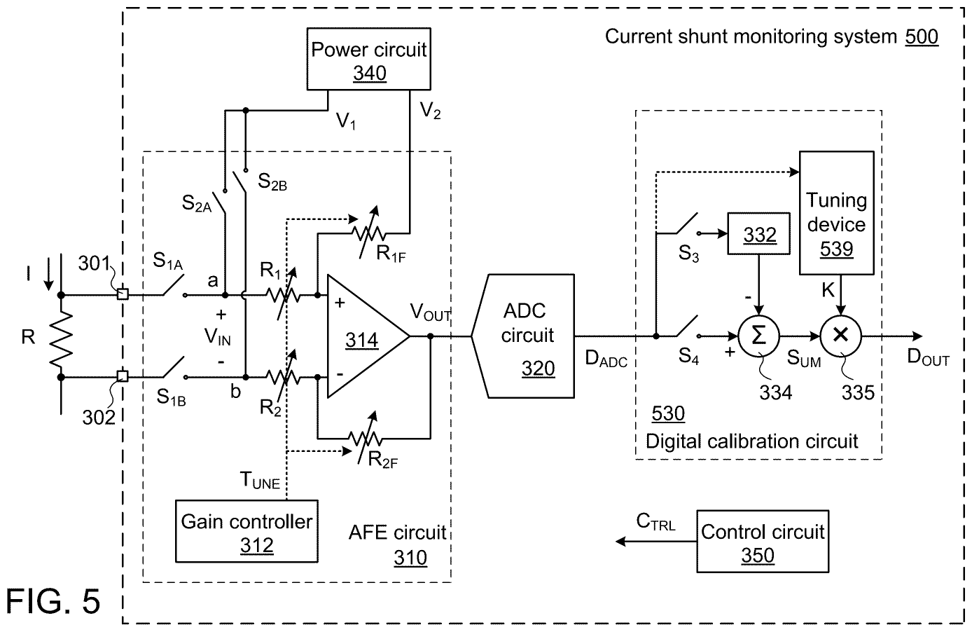

FIG. 5 is a schematic circuit diagram illustrating the detailed circuitry structure of a current shunt monitoring system according to a second embodiment of the present invention. When compared with the current shunt monitoring system of the first embodiment, the digital calibration circuit 530 in the current shunt monitoring system 500 of this embodiment further includes a tuning device 539 to dynamically adjust the correction ratio K. The connecting relationships between other components in this embodiment are similar to those of the first embodiment, and not redundantly described herein.

As shown in FIG. 5, the tuning device 539 in the digital calibration circuit 530 is connected to the output terminal of the ADC circuit 320. During multiple calibration periods of the current shunt monitoring system 500, the tuning device 539 receives a plurality of digital error values. The tuning device 539 further updates the correction ratio K according to the gain G of the AFE circuit 310 and the digital error values. In addition, the updated correction ratio K is transmitted to the multiplier 335.

The advanced calibration process for the current shunt monitoring system 500 of the second embodiment will be described as follows. The advanced calibration procedure includes an initial calibration procedure, a normal operation procedure and an in-operation calibration procedure. The initial calibration procedure may be regarded as a first calibration procedure. The normal operation procedure may be regarded as a second calibration procedure. Furthermore, the current shunt monitoring system 500 can perform in-operation calibration procedure during the normal operation procedure. Meanwhile, the current shunt monitoring system 500 suspends the normal operation procedure but performs the in-operation calibration procedure. When the in-operation calibration procedure is performed, the digital error value stored in the storage device 332 of the digital calibration circuit 530 is updated, and the correction ratio K is also updated. After correction ratio K is updated, the current shunt monitoring system 500 performs the normal operation procedure again.

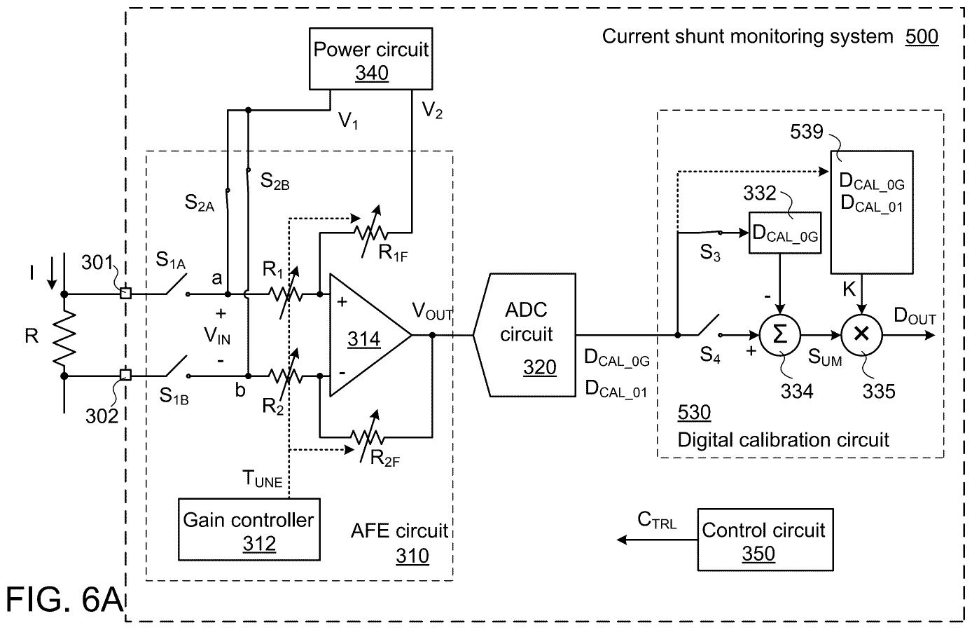

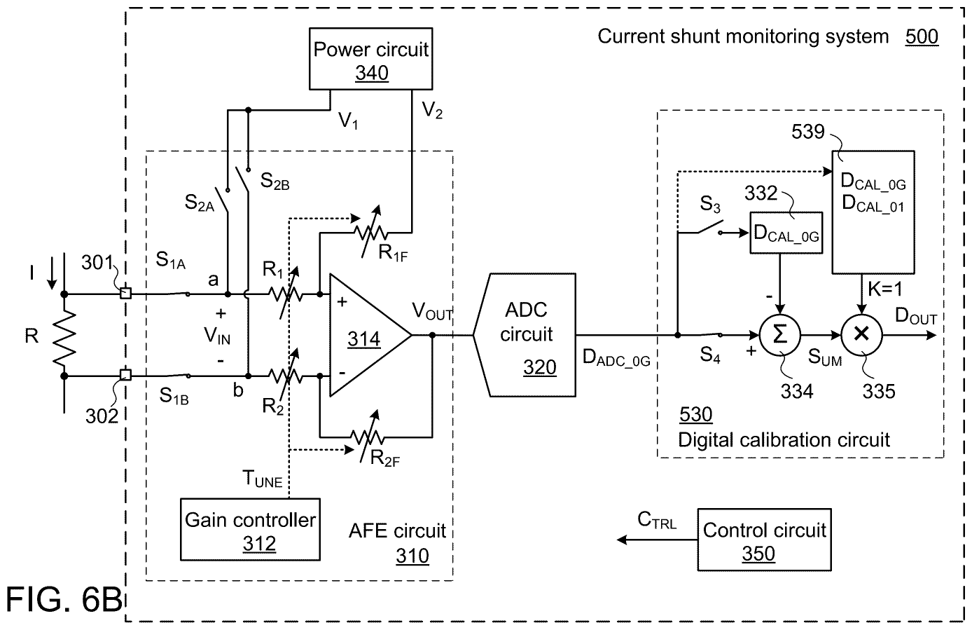

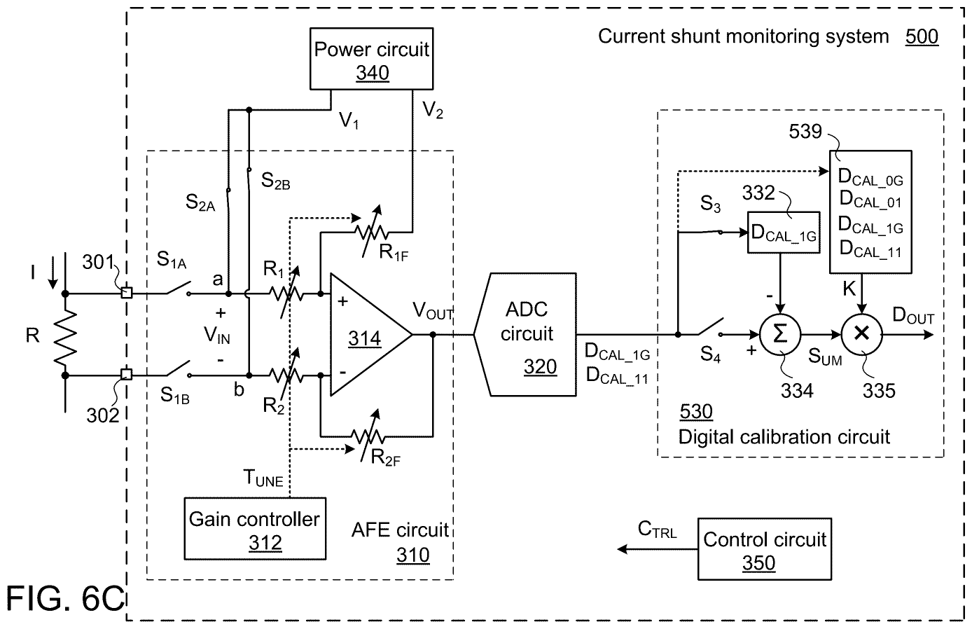

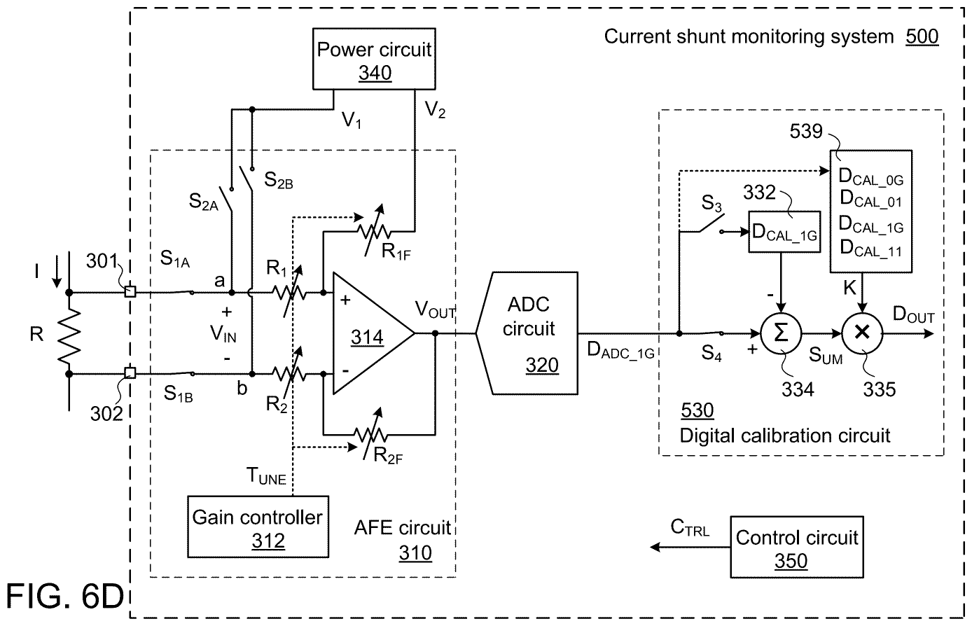

FIGS. 6A, 6B, 6C and 6D are schematic circuit diagrams illustrating a first example of an advanced calibration procedure for the current shunt monitoring system in the second embodiment of the present invention. The time period of performing the initial calibration procedure is divided into a first period and a second period.

Please refer to FIG. 6A. During the first period of the initial calibration procedure, the switches S_{1A}, S_{1B} and S₄ are in the off state and the switches S_{2A}, S_{2B} and S₃ are in the on state under control of the control circuit 350. In addition, the gain of the differential amplifier 314 is adjusted to G by the gain controller 312. For example, G=(R_{2F}/R₂), in which G is greater than 1. In this situation, the two input terminals of the AFE circuit 310 are not connected to the external resistor R, and the input terminals of the AFE circuit 310 receive the same first voltage V₁. In other words, the input voltage V_{IN} is equal to zero. Consequently, the ADC circuit 320 generates a first digital error value D_{CAL_0G}. In addition, the first digital error value D_{CAL_0G} is stored in the tuning device 539 and the storage device 332 of the digital calibration circuit 530.

In other words, D_{CAL_0G}=V_{OS0}×(G+1)+V_{AFE_ERR}+V_{ADC_ERR}+V₂. In this formula, V_{OS0} is the input offset of the differential amplifier 314 during the initial calibration procedure, the input offset V_{OS0} is amplified by (G+1) times, V_{AFE_ERR} indicates other errors of the differential amplifier 314, V_{ADC_ERR} is the error of the ADC circuit 320, and the minimum value of the output voltage V_{OUT} of the differential amplifier 314 is set according to the second voltage V₂.

Please refer to FIG. 6A again. During the second period of the initial calibration procedure, the switches S_{1A}, S_{1B} and S₄ are in the off state and the switches S_{2A}, S_{2B} and S₃ are in the on state under control of the control circuit 350. In addition, only the gain of the differential amplifier 314 is adjusted to G=1 by the gain controller 312. For example, the two resistors R_{2F} and R₂ are adjusted to have the same resistance value. Consequently, the ADC circuit 320 generates a second digital error value D_{CAL_01}. In addition, the second digital error value D_{CAL_01} is stored in the tuning device 539 of the digital calibration circuit 530 only. For example, D_{CAL_01}=V_{OS0}×(1+1)+V_{AFE_ERR}+V_{ADC_ERR}+V₂.

After the initial calibration procedure is completed, the normal operation procedure of the current shunt monitoring system 500 is performed. Please refer to FIG. 6B. During the normal operation procedure, the switches S_{1A}, S_{1B} and S₄ are in the on state and the switches S_{2A}, S_{2B} and S₃ are in the off state under control of the control circuit 350. In addition, the gain of the differential amplifier 314 is adjusted to G by the gain controller 312. In this situation, the input terminals of the AFE circuit 310 are connected to the external resistor R, and the ADC circuit 320 generates a digital operation value D_{ADC_0G}. For example, D_{ADC_0G}=V_{IN}×G+V_{OS1}×(G+1)+V_{AFE_ERR}+V_{ADC_ERR}+V₂. In this formula, V_{OS1} is the input offset of the differential amplifier 314 during the normal operation procedure.

Furthermore, the first digital error value D_{CAL_0G} stored in storage device 332 of the digital calibration circuit 530 corresponding to the initial calibration procedure is outputted. As mentioned above, the AFE circuit 310 does not generate the gain deviation and the offset deviation when the initial calibration procedure of the current shunt monitoring system 500 is switched to the normal operation procedure. Consequently, the two input offsets V_{OS0} and V_{OS1} are approximately equal, and the correction ratio K is set to 1. In other words, the principles of the initial calibration procedure and the normal operation procedure in the advanced calibration procedure are similar to the principles of the standard calibration procedure. Consequently, the digital calibration circuit 530 generates the calibrated output value D_{OUT}. The calibrated output value D_{OUT} may be expressed as: D_{OUT}=(D_{ADC_0G}−D_{CAL_0G})×K=(I×R)×G. Under this circumstance, the calibrated output value D_{OUT} from the digital calibration circuit 530 can accurately reflect the voltage drop I×R across the resistor R, and the calibrated output value D_{OUT} can also accurately reflect the magnitude of the current I flowing through the resistor R.

After the current shunt monitoring system 500 has been normally operated for a certain time period, the gain deviation and the offset deviation of the AFE circuit 310 will become increasingly serious. Meanwhile, the gain is adjusted from G to (G+ΔG), and the input offset V_{OS0} and the input offset V_{OS1} are not equal. Under this circumstance, it is necessary to perform the in-operation calibration procedure. Similarly, the time period of performing the in-operation calibration procedure is divided into a first period and a second period.

Please refer to FIG. 6C. During the first period of the in-operation calibration procedure, the switches S_{1A}, S_{1B} and S₄ are in the off state and the switches S_{2A}, S_{2B} and S₃ are in the on state under control of the control circuit 350. In addition, the gain of the differential amplifier 314 is adjusted to G by the gain controller 312. For example, G=(R_{2F}/R₂). In this situation, the two input terminals of the AFE circuit 310 are not connected to the external resistor R, and the input terminals of the AFE circuit 310 receive the same first voltage V₁. In other words, the input voltage V_{IN} is equal to zero. Consequently, the ADC circuit 320 generates a third digital error value D_{CAL_1G}. In addition, the third digital error value D_{CAL_1G} is stored in the tuning device 539 and the storage device 332 of the digital calibration circuit 530. In other words, D_{CAL_1G}=V_{OS1}×(G+ΔG+1)+V_{AFE_ERR}+V_{ADC_ERR}+V₂.

Please refer to FIG. 6C again. During the second period of the in-operation calibration procedure, the switches S_{1A}, S_{1B} and S₄ are in the off state and the switches S_{2A}, S_{2B} and S₃ are in the on state under control of the control circuit 350. In addition, only the gain of the differential amplifier 314 is adjusted to G=1 by the gain controller 312. For example, the two resistors R_{2F} and R₂ are adjusted to have the same resistance value. Consequently, the ADC circuit 320 generates a fourth digital error value D_{CAL_11}. In addition, the fourth digital error value D_{CAL_11} is stored in the tuning device 539 of the digital calibration circuit 530 only. For example, D_{CAL_11}=V_{OS0}×(1+1)+V_{AFE_ERR}+V_{ADC_ERR}+V₂.

After the in-operation calibration procedure is completed, the normal operation procedure of the current shunt monitoring system 500 is performed again. Please refer to FIG. 6D. During the normal operation procedure, the switches S_{1A}, S_{1B} and S₄ are in the on state and the switches S_{2A}, S_{2B} and S₃ are in the off state under control of the control circuit 350. In addition, the gain of the differential amplifier 314 is adjusted to G by the gain controller 312. In this situation, the input terminals of the AFE circuit 310 are connected to the external resistor R, and the ADC circuit 320 generates a digital operation value D_{ADC_1G}. For example, D_{ADC_1G}=V_{IN}×(G+ΔG)+V_{OS1}×(G+ΔG+1)+V_{AFE_ERR}+V_{ADC_ERR}+V₂.

Furthermore, the third digital error value D_{CAL_1G} stored in storage device 332 of the digital calibration circuit 530 corresponding to the in-operation calibration procedure is outputted. Consequently, the digital calibration circuit 530 generates the calibrated output value D_{OUT}. The calibrated output value D_{OUT} may be expressed as: D_{OUT}=(D_{ADC_1G}−D_{CAL_1G})×K=I×R×(G+ΔG)×K. For allowing the calibrated output value D_{OUT} to accurately reflect the voltage drop I×R of the resistor R, the correction ratio K needs to be updated as [G/(G+ΔG)] by the tuning device 539.

In an embodiment, the tuning device 539 calculates an updated correction ratio K according to the gain value G and the four digital error values D_{CAL_0G}, D_{CAL_01}, D_{CAL_1G} and D_{CAL_11}. A calculating method of the tuning device 539 will be described as follows.

Firstly, a value M and the correction ratio K are sequentially calculated:

$$M = \frac{{D}_{CAL\_ 1 G} - {D}_{CAL\_ 11}}{( {D}_{CAL\_ 1 G} - {D}_{CAL\_ 0 G} ) - \frac{( {D}_{CAL\_ 11} - {D}_{CAL\_ 01} )}{2} - \frac{( {D}_{CAL\_ 11} - {D}_{CAL\_ 01} ) \times G}{2} = \frac{( G + Δ G - 1 )}{Δ G}}$$

$$K = \frac{G}{( G + Δ G )} = \frac{G}{G + \frac{G - 1}{M - 1}}$$

As mentioned above, after the in-operation calibration procedure is completed, the normal operation procedure of the current shunt monitoring system 500 is performed again. During the normal operation procedure, the tuning device 539 provides the updated correction ratio K. Under this circumstance, the calibrated output value D_{OUT} can accurately reflect the voltage drop I×R across the resistor R. Furthermore, the calibrated output value D_{OUT} can also accurately reflect the magnitude of the current I flowing through the resistor R.

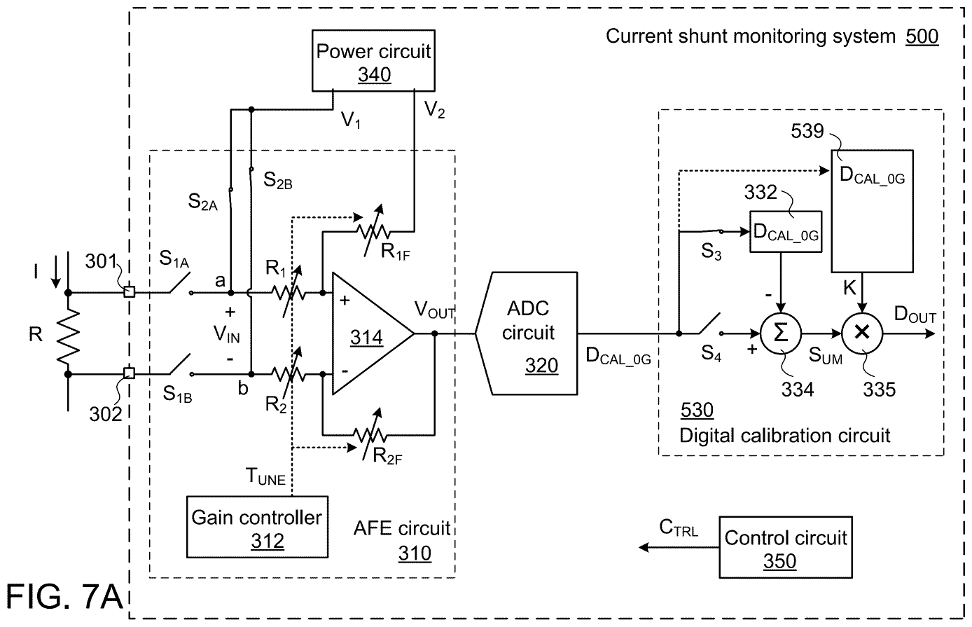

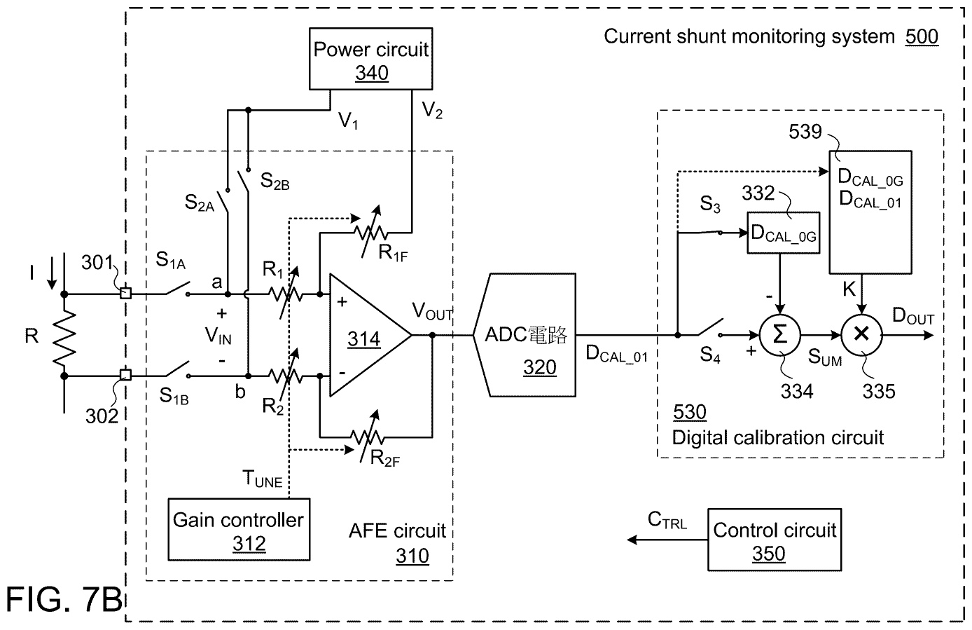

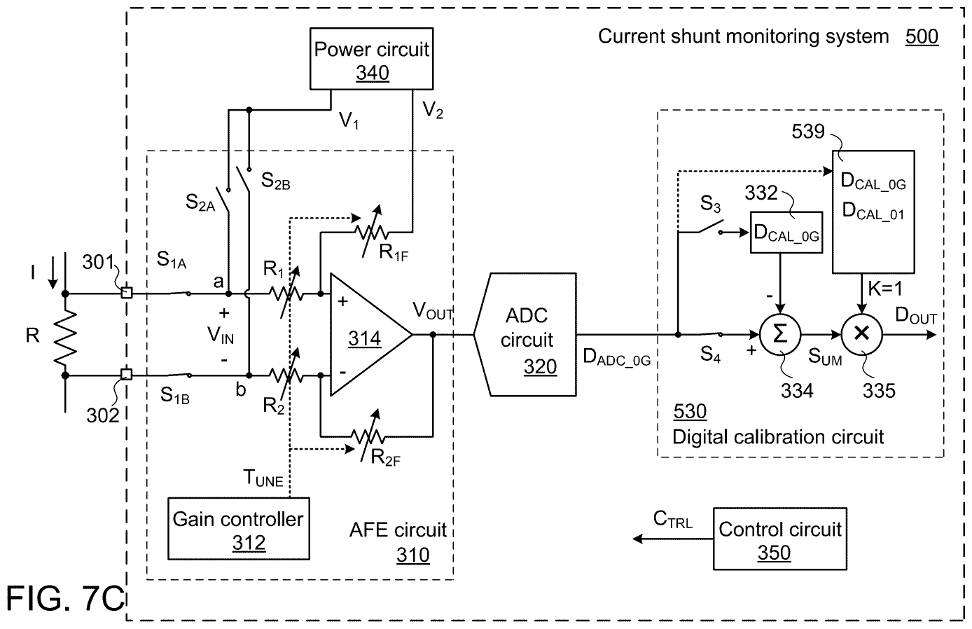

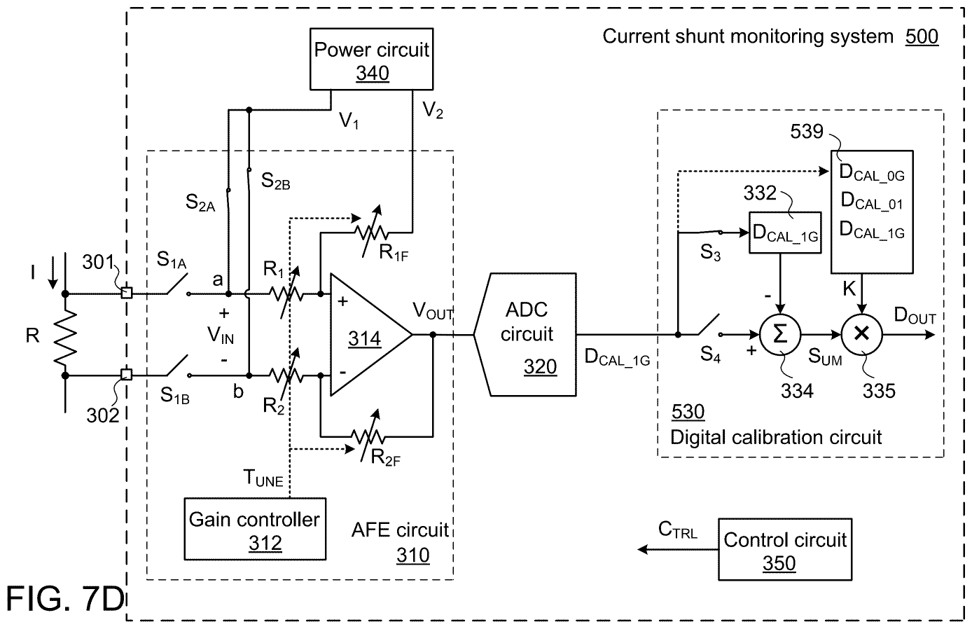

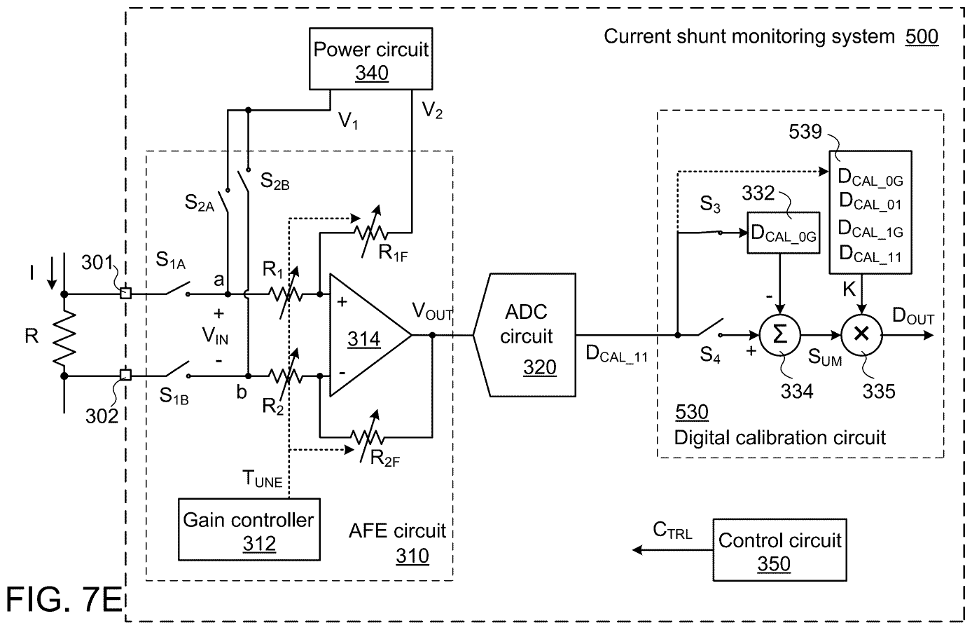

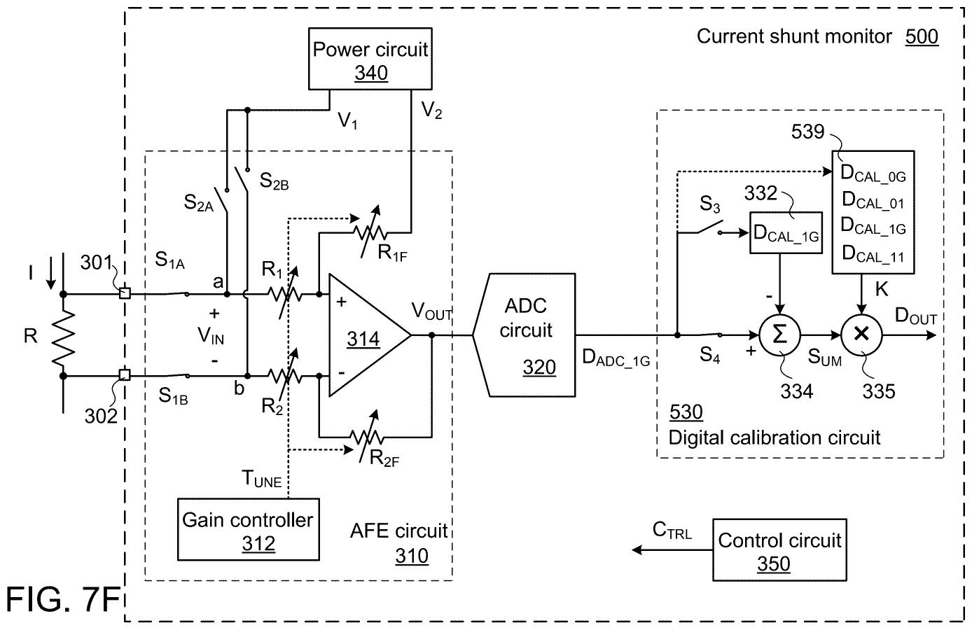

FIGS. 7A, 7B, 7C, 7D, 7E and 7F are schematic circuit diagrams illustrating a second example of an advanced calibration procedure for the current shunt monitoring system in the second embodiment of the present invention. In comparison with the first example, the switch S_{2B} is in the off state during the second time period of the advanced calibration procedure of this embodiment.

Please refer to FIG. 7A. During the first period of the initial calibration procedure, the switches S_{1A}, S_{1B} and S₄ are in the off state and the switches S_{2A}, S_{2B} and S₃ are in the on state under control of the control circuit 350. In addition, the gain of the differential amplifier 314 is adjusted to G by the gain controller 312. For example, G=(R_{2F}/R₂), in which G is greater than 1. Consequently, the ADC circuit 320 generates a first digital error value D_{CAL_0G}. In addition, the first digital error value D_{CAL_0G} is stored in the tuning device 539 and the storage device 332 of the digital calibration circuit 530.

In other words, D_{CAL_0G}=V_{OS0}×(G+1)+V_{AFE_ERR}+V_{ADC_ERR}+V₂. In this formula, V_{OS0} is the input offset of the differential amplifier 314 during the initial calibration procedure, the input offset V_{OS0} is amplified by (G+1) times, V_{AFE_ERR} indicates other errors of the differential amplifier 314, V_{ADC_ERR} is the error of the ADC circuit 320, and the minimum value of the output voltage V_{OUT} of the differential amplifier 314 is set according to the second voltage V₂.

Please refer to FIG. 7B. During the second period of the initial calibration procedure, the switches S_{1A}, S_{1B}, S_{2A}, S_{2B} and S₄ are in the off state and the switch S₃ is in the on state under control of the control circuit 350. In addition, the gain of the differential amplifier 314 is adjusted to G=1 by the gain controller 312. For example, the two resistors R_{2F} and R₂ are adjusted to have the same resistance value. Consequently, the ADC circuit 320 generates a second digital error value D_{CAL_01}. In addition, the second digital error value D_{CAL_01} is stored in the tuning device 539 of the digital calibration circuit 530 only. For example, D_{CAL_01}=V_{OS0}+V_{AFE_ERR}+V_{ADC_ERR}+V₂.

After the initial calibration procedure is completed, the normal operation procedure of the current shunt monitoring system 500 is performed. Please refer to FIG. 7C. During the normal operation procedure, the switches S_{1A}, S_{1B} and S₄ are in the on state and the switches S_{2A}, S_{2B} and S₃ are in the off state under control of the control circuit 350. In addition, the gain of the differential amplifier 314 is adjusted to G by the gain controller 312. In this situation, the input terminals of the AFE circuit 310 are respectively connected to the two terminals of the external resistor R, and the ADC circuit 320 generates a digital operation value D_{ADC_0G}. For example, D_{ADC_0G}=V_{IN}×G+V_{OS1}×(G+1)+V_{AFE_ERR}+V_{ADC_ERR}+V₂. In this formula, V_{OS1} is the input offset of the differential amplifier 314 during the normal operation procedure.

Furthermore, the first digital error value D_{CAL_0G} stored in storage device 332 of the digital calibration circuit 530 corresponding to the initial calibration procedure is outputted. As mentioned above, the AFE circuit 310 does not generate the gain deviation and the offset deviation when the initial calibration procedure of the current shunt monitoring system 500 is switched to the normal operation procedure. Consequently, the two input offsets V_{OS0} and V_{OS1} are approximately equal, and the correction ratio K is set to 1. In other words, the principles of the initial calibration procedure and the normal operation procedure in the advanced calibration procedure are similar to the principles of the standard calibration procedure. Consequently, the digital calibration circuit 530 generates the calibrated output value D_{OUT}. The calibrated output value D_{OUT} may be expressed as: D_{OUT}=(D_{ADC_0G}−D_{CAL_0G})×K=(I×R)×G. Under this circumstance, the calibrated output value D_{OUT} from the digital calibration circuit 530 can accurately reflect the voltage drop I×R across the resistor R, and the calibrated output value D_{OUT} can also accurately reflect the magnitude of the current I flowing through the resistor R.

After the current shunt monitoring system 500 has been normally operated for a certain time period, the gain deviation and the offset deviation of the AFE circuit 310 will become increasingly serious. Meanwhile, the gain is adjusted from G to (G+ΔG), and the input offset V_{OS0} and the input offset V_{OS1} are not equal. Under this circumstance, it is necessary to perform the in-operation calibration procedure. Similarly, the time period of performing the in-operation calibration procedure is divided into a first period and a second period.

Please refer to FIG. 7D. During the first period of the in-operation calibration procedure, the switches S_{1A}, S_{1B} and S₄ are in the off state and the switches S_{2A}, S_{2B} and S₃ are in the on state under control of the control circuit 350. In addition, the gain of the differential amplifier 314 is adjusted to G by the gain controller 312. For example, G=(R_{2F}/R₂). Consequently, the ADC circuit 320 generates a third digital error value D_{CAL_1G}. In addition, the third digital error value D_{CAL_1G} is stored in the tuning device 539 and the storage device 332 of the digital calibration circuit 530. For example, D_{CAL_1G}=V_{OS1}×(G+ΔG+1)+V_{AFE_ERR}+V_{ADC_ERR}+V₂.

Please refer to FIG. 7E again. During the second period of the in-operation calibration procedure, the switches S_{1A}, S_{1B}, S_{2A}, S_{2B} and S₄ are in the off state and the switch S₃ is in the on state under control of the control circuit 350. In addition, only the gain of the differential amplifier 314 is adjusted to G=1 by the gain controller 312. For example, the two resistors R_{2F} and R₂ are adjusted to have the same resistance value. Consequently, the ADC circuit 320 generates a fourth digital error value D_{CAL_11}. In addition, the fourth digital error value D_{CAL_11} is stored in the tuning device 539 of the digital calibration circuit 530 only. For example, D_{CAL_11}=V_{OS0}+V_{AFE_ERR}+V_{ADC_ERR}+V₂.

After the in-operation calibration procedure is completed, the normal operation procedure of the current shunt monitoring system 500 is performed again. Please refer to FIG. 7F. During the normal operation procedure, the switches S_{1A}, S_{1B} and S₄ are in the on state and the switches S_{2A}, S_{2B} and S₃ are in the off state under control of the control circuit 350. In addition, the gain of the differential amplifier 314 is adjusted to G by the gain controller 312. In this situation, the input terminals of the AFE circuit 310 are respectively connected to the two terminals of the external resistor R, and the ADC circuit 320 generates a digital operation value D_{ADC_1G}. For example, D_{ADC_1G}=V_{IN}×(G+ΔG)+V_{OS1}×(G+ΔG+1)+V_{AFE_ERR}+V_{ADC_ERR}+V₂.

Furthermore, the third digital error value D_{CAL_1G} stored in storage device 332 of the digital calibration circuit 530 corresponding to the in-operation calibration procedure is outputted. Consequently, the digital calibration circuit 530 generates the calibrated output value D_{OUT}. The calibrated output value D_{OUT} may be expressed as: D_{OUT}=(D_{ADC_1G}−D_{CAL_1G})×K=I×Rx (G+ΔG)×K. For allowing the calibrated output value D_{OUT} to accurately reflect the voltage drop I×R of the resistor R, the correction ratio K needs to be updated as [G/(G+ΔG)] by the tuning device 539.

In an embodiment, the tuning device 539 calculates an updated correction ratio K according to the gain value G and the four digital error values D_{CAL_0G}, D_{CAL_01}, D_{CAL_1G} and D_{CAL_11}. A calculating method of the tuning device 539 will be described as follows.

Firstly, the correction ratio K is calculated:

$$K = \frac{( {D}_{CAL \_ 0 G} - {D}_{{CAL}_{01}} ) + ( {D}_{CAL\_ 11} - {D}_{CAL\_ 01} ) \times G}{( {D}_{CAL\_ 1 G} - {D}_{CAL\_ 11} )} = \frac{G}{( G + Δ G )}$$

As mentioned above, after the in-operation calibration procedure is completed, the normal operation procedure of the current shunt monitoring system 500 is performed again. During the normal operation procedure, the tuning device 539 provides the updated correction ratio K. Under this circumstance, the calibrated output value D_{OUT} can accurately reflect the voltage drop I×R across the resistor R. Furthermore, the calibrated output value D_{OUT} can also accurately reflect the magnitude of the current I flowing through the resistor R.

From the above descriptions, the present invention provides a current shunt monitoring system. A standard calibration procedure is used to calibrate the error generated by each circuit in the current shunt monitoring system. The error at least includes the offset of the circuit and the CMRR change of the circuit. The present invention further provides an advanced calibration procedure to eliminate the gain deviation and the offset deviation of the AFE circuit.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A current shunt monitoring system connected to a resistor, a current flowing through the resistor to generate a voltage drop, the current shunt monitoring system comprising:
an analog front end circuit, wherein a first input terminal of the analog front end circuit is connected to a first terminal of the resistor, and a second input terminal of the analog front end circuit is connected to a second terminal of the resistor;
an analog-to-digital circuit, wherein an input terminal of the analog-to-digital circuit is connected to an output terminal of the analog front end circuit to receive an output voltage, and the output voltage is converted by the analog front end circuit; and
a digital calibration circuit, wherein an input terminal of the digital calibration circuit is connected to an output terminal of the analog-to-digital circuit,
wherein when a first calibration procedure is performed, the analog front end circuit receives an input voltage, the input voltage is zero, and the analog-to-digital circuit generates a first digital error value to the digital calibration circuit,
wherein after the first calibration procedure is completed, a normal operation procedure is performed, wherein during the normal operation procedure, the input voltage received by the analog front end circuit is equal to the voltage drop, and the analog-to-digital circuit generates a first digital operation value to the digital calibration circuit,
wherein during the normal operation procedure, the digital calibration circuit subtracts the first digital error value from the first digital operation value to obtain a summed value, multiplies the summed value by a correction ratio to obtain a calibrated output value, and outputs the calibrated output value.

2. The current shunt monitoring system as claimed in claim 1, further comprising a power circuit, wherein a first power terminal of the power circuit outputs a first voltage to the analog front end circuit, and a second power terminal of the power circuit outputs a second voltage to the analog front end circuit.

3. The current shunt monitoring system as claimed in claim 2, wherein the analog front end circuit comprises:
a differential amplifier;
a first switch, wherein a first terminal of the first switch is connected to a first terminal of the resistor, and a second terminal of the first switch is connected to a first node;
a second switch, wherein a first terminal of the second switch is connected to a second terminal of the resistor, and a second terminal of the second switch is connected to a second node;
a third switch, wherein a first terminal of the third switch is connected to the first node, and a second terminal of the third switch is connected to the first power terminal of the power circuit;
a fourth switch, wherein a first terminal of the fourth switch is connected to the second node, and a second terminal of the fourth switch is connected to the first power terminal of the power circuit;
a first variable resistor, wherein a first terminal of the first variable resistor is connected to the first node, and a second terminal of the first variable resistor is connected to a first input terminal of the differential amplifier;
a second variable resistor, wherein a first terminal of the second variable resistor is connected to the second power terminal of the power circuit, and a second terminal of the second variable resistor is connected to the first input terminal of the differential amplifier;
a third variable resistor, wherein a first terminal of the third variable resistor is connected to the second node, and a second terminal of the third variable resistor is connected to a second input terminal of the differential amplifier;
a fourth variable resistor, wherein a first terminal of the fourth variable resistor is connected to an output terminal of the differential amplifier, and a second terminal of the fourth variable resistor is connected to the second input terminal of the differential amplifier; and
a gain controller connected to the first variable resistor, the second variable resistor, the third variable resistor and the fourth variable resistor, wherein the gain controls the analog front end circuit to have a first gain.

4. The current shunt monitoring system as claimed in claim 3, wherein the gain controller generates an adjustment signal to the control terminals of the first variable resistor, the second variable resistor, the third variable resistor and the fourth variable resistor, so that resistance values of the first variable resistor, the second variable resistor, the third variable resistor and the fourth variable resistor are correspondingly adjusted.

5. The current shunt monitoring system as claimed in claim 4, wherein a ratio of the resistance value of the first variable resistor to a resistance value of the second variable resistor is equal to a ratio of the resistance value of the third variable resistor to the resistance value of the fourth variable resistor.

6. The current shunt monitoring system as claimed in claim 3, wherein the digital calibration circuit comprises:
an adder;
a storage device;
a fifth switch, wherein a first terminal of the fifth switch is connected to an output terminal of the analog-to-digital circuit, a second terminal of the fifth switch is connected to an input terminal of the storage device, and an output terminal of the storage device is connected to a first input terminal of the adder;
a sixth switch, wherein a first terminal of the sixth switch is connected to the output terminal of the analog-to-digital circuit, and a second terminal of the sixth switch is connected to a second input terminal of the adder, wherein during the normal operation procedure, the first digital error received by the first input terminal of the adder is subtracted from the first digital operation value received by the second input terminal of the adder, so that the summed value is obtained; and
a multiplier, wherein a first input terminal of the multiplier receives the summed value, a second input terminal of the multiplier receives the correction ratio, and a multiplication result of the summed value and the correction ratio is obtained by the multiplier, wherein the multiplication result is the calibrated output value, and the calibrated output value is outputted from an output terminal of the multiplier.

7. The current shunt monitoring system as claimed in claim 6, wherein during the first calibration procedure, the first switch, the second switch and the sixth switch are in an off state, the third switch, the fourth switch and the fifth switch are in an on state, the input voltage is zero, and the analog-to-digital circuit outputs the first digital error value to the storage device.

8. The current shunt monitoring system as claimed in claim 7, wherein during the normal operation procedure, the first switch, the second switch and the sixth switch are in the on state, the third switch, the fourth switch and the fifth switch are in the off state, the input voltage is equal to the voltage drop, and the analog-to-digital circuit outputs the first digital operation value to the second input terminal of the adder.

9. The current shunt monitoring system as claimed in claim 8, wherein the correction ratio is a constant.

10. The current shunt monitoring system as claimed in claim 6, wherein the digital calibration circuit further comprises a tuning device, wherein an input terminal of the tuning device is connected to the output terminal of the analog-to-digital circuit, and an input terminal of the tuning device is connected to the second input terminal of the multiplexer.

11. The current shunt monitoring system as claimed in claim 10, wherein during a first period of the first calibration procedure, the first switch, the second switch and the sixth switch are in an off state, the third switch, the fourth switch and the fifth switch are in an on state, the first gain of the analog front end circuit is greater than 1, the input voltage is zero, and the analog-to-digital circuit outputs the first digital error value to the storage device and the tuning device.

12. The current shunt monitoring system as claimed in claim 11, wherein during a second period of the first calibration procedure, the first switch, the second switch and the sixth switch are in the off state, the third switch, the fourth switch and the fifth switch are in the on state, the first gain of the analog front end circuit is greater than 1, the input voltage is zero, and the analog-to-digital circuit outputs a second digital error value to the tuning device.

13. The current shunt monitoring system as claimed in claim 12, wherein during the normal operation procedure, the first switch, the second switch and the sixth switch are in the on state, the third switch, the fourth switch and the fifth switch are in the off state, the input voltage is equal to the voltage drop, and the analog-to-digital circuit outputs the first digital operation value to the second input terminal of the adder.

14. The current shunt monitoring system as claimed in claim 13, wherein a second calibration procedure is performed during the normal operation procedure, wherein during a first period of the second calibration procedure, the first switch, the second switch and the sixth switch are in the off state, the third switch, the fourth switch and the fifth switch are in the on state, the first gain of the analog front end circuit is greater than 1, the input voltage is zero, and the analog-to-digital circuit outputs a third digital error value to the storage device and the tuning device.

15. The current shunt monitoring system as claimed in claim 14, wherein during a second period of the second calibration procedure, the first switch, the second switch and the sixth switch are in the off state, the third switch, the fourth switch and the fifth switch are in the on state, the first gain of the analog front end circuit is greater than 1, the input voltage is zero, and the analog-to-digital circuit outputs a fourth digital error value to the tuning device, wherein the tuning device calculates an updated correction ratio according to the first digital error value, the second digital error value, the third digital error value and the fourth digital error value.

16. The current shunt monitoring system as claimed in claim 15, wherein after the second period of the second calibration procedure, the normal operation procedure is performed again, wherein during the normal operation procedure, the first switch, the second switch and the sixth switch are in the on state, the third switch, the fourth switch and the fifth switch are in the off state, the input voltage is equal to the voltage drop, and the analog-to-digital circuit outputs a second digital operation value to the second input terminal of the adder.

17. The current shunt monitoring system as claimed in claim 16, wherein after the second period of the second calibration procedure and the normal operation procedure is performed again, the digital calibration circuit subtracts the third digital error value from the second digital operation value to obtain the summed value, and the digital calibration circuit multiplies the summed value by the updated correction ratio to obtain the calibrated output value.

18. The current shunt monitoring system as claimed in claim 10, wherein during a first period of the first calibration procedure, the first switch, the second switch and the sixth switch are in an off state, the third switch, the fourth switch and the fifth switch are in an on state, the first gain of the analog front end circuit is greater than 1, the input voltage is zero, and the analog-to-digital circuit outputs the first digital error value to the storage device and the tuning device.

19. The current shunt monitoring system as claimed in claim 18, wherein during a second period of the first calibration procedure, the first switch, the second switch, the third switch, the fourth switch and the sixth switch are in the off state, the fifth switch is in the on state, the first gain of the analog front end circuit is equal to 1, the input voltage is zero, and the analog-to-digital circuit outputs a second digital error value to the tuning device.

20. The current shunt monitoring system as claimed in claim 19, wherein during the normal operation procedure, the first switch, the second switch and the sixth switch are in the on state, the third switch, the fourth switch and the fifth switch are in the off state, the input voltage is equal to the voltage drop, and the analog-to-digital circuit outputs the first digital operation value to the second input terminal of the adder.

21. The current shunt monitoring system as claimed in claim 20, wherein a second calibration procedure is performed during the normal operation procedure, wherein during a first period of the second calibration procedure, the first switch, the second switch and the sixth switch are in the off state, the third switch, the fourth switch and the fifth switch are in the on state, the first gain of the analog front end circuit is greater than 1, the input voltage is zero, and the analog-to-digital circuit outputs a third digital error value to the storage device and the tuning device.

22. The current shunt monitoring system as claimed in claim 21, wherein during a second period of the second calibration procedure, the first switch, the second switch, the third switch, the fourth switch and the sixth switch are in the off state, the fifth switch is in the on state, the first gain of the analog front end circuit is greater than 1, the input voltage is zero, and the analog-to-digital circuit outputs a fourth digital error value to the tuning device, wherein the tuning device calculates an updated correction ratio according to the first digital error value, the second digital error value, the third digital error value and the fourth digital error value.

23. The current shunt monitoring system as claimed in claim 22, wherein after the second period of the second calibration procedure, the normal operation procedure is performed again, wherein during the normal operation procedure, the first switch, the second switch and the sixth switch are in the on state, the third switch, the fourth switch and the fifth switch are in the off state, the input voltage is equal to the voltage drop, and the analog-to-digital circuit outputs a second digital operation value to the second input terminal of the adder.

24. The current shunt monitoring system as claimed in claim 23, wherein after the second period of the second calibration procedure and the normal operation procedure is performed again, the digital calibration circuit subtracts the third digital error value from the second digital operation value to obtain the summed value, and the digital calibration circuit multiplies the summed value by the updated correction ratio to obtain the calibrated output value.
